(19) United States
(12) Patent Application Publication
(10) Pub. No.: US 2010/0244265 A1
(43) Pub. Date: Sep. 30, 2010

(54) SEMICONDUCTOR DEVICE AND METHOD FOR MANUFACTURING THE SAME

(75) Inventor: Shuji Hirao, Hyogo (JP)

Correspondence Address: HAMRE, SCHUMANN, MUELLER & LARSON P.C., P.O. BOX 2902, MINNEAPOLIS, MN, 55402-0902, US

(73) Assignee: PANASONIC CORPORATION, Osaka (JP)

(21) Appl. No.: 12/813,699

(22) Filed: Jun. 11, 2010

Related U.S. Application Data
(63) Continuation of application No. PCT/JP2008/002996, filed on Oct. 23, 2008.

(30) Foreign Application Priority Data
Dec. 12, 2007 (JP) 2007-320268

(51) Int. Cl. H01L 23/522; H01L 21/768

(52) U.S. Cl. 257/758; 438/637; 257/E23.142; 257/E21.585

(57) ABSTRACT

Wiring grooves are formed on a first interlayer insulating film 2 on a semiconductor substrate 1; first Cu wires 5 are formed by stacking first Cu films 4 in the wiring grooves; a first liner film 6 is formed on the first Cu wires 5 and the first interlayer insulating film 2; openings 13 are partially formed on the first Cu wires 5 so as to expose the surfaces of the first Cu wires 5 on the first liner film 6; and cap metal films 7 are formed on the surfaces of the first Cu wires 5 exposed in the openings 13.

### TECHNICAL FIELD

The present invention relates to a semiconductor device in which copper is used as a wiring material and a method for manufacturing the same, and specifically relates to a wiring forming technique using a damascene process.

### BACKGROUND ART

In the prior art, aluminum has been a main wiring material of LSIs formed on semiconductor substrates in semiconductor devices. As semiconductor ICs have become faster with higher integration in recent years, copper (Cu) has attracted attention as a wiring material. Copper has lower resistance than aluminum and has high resistance to electromigration (EM).

Referring to FIGS. 10(a) to 10(e), 11, and 12, the following will describe a method for forming copper wires by a damascene process in a semiconductor device of the prior art (e.g., see National Publication of International Patent Application No. 2003-505882).

FIG. 10 is a sectional view showing the steps of forming the copper wires in a method for manufacturing the semiconductor device of the prior art. FIG. 11 is a plan view showing the semiconductor device formed by the copper wire forming method of FIG. 10. FIG. 12 is a sectional view showing the semiconductor device taken along line A-A′ of FIG. 11 according to the prior art. FIG. 10(e) is a sectional view showing the semiconductor device taken along line B-B′ of FIG. 11 according to the prior art.

First, as shown in FIG. 10(a), wiring grooves 102 are formed on a first interlayer insulating film 101 formed on a semiconductor substrate 100. After that, a first barrier metal film 103 and a seed Cu film 104 are sequentially formed over the first interlayer insulating film 101 as well as in the wiring grooves 102.

Next, as shown in FIG. 10(b), the insides of the wiring grooves 102 are filled with a Cu film by electrolytic plating. After that, the Cu film is annealed at, e.g., about 150° to 300° to stabilize the Cu film. Consequently, the plating Cu film and the seed Cu film 104 are integrated to form a first Cu film 105.

Next, as shown in FIG. 10(c), the excessive first Cu film 105 and first barrier metal film 103 outside the wiring grooves 102 are removed by chemical-mechanical polishing (CMP), so that Cu wires are formed.

After that, as shown in FIG. 10(d), displacement plating of Pd is performed on the first Cu films 105 with Pd ions serving as catalysts on the surfaces of the Cu wires. Next, electroless reduction is performed thereon with Pd serving as nuclei, so that cap metal films 108, each of which includes a film such as a CoWP film, are selectively grown only on the surfaces of the Cu wires.

Next, as shown in FIG. 10(e), a liner film 106 and a second interlayer insulating film 107 are sequentially stacked on the interlayer insulating film 101 containing the Cu wires.

In this configuration, the liner film 106 is a film not containing oxygen, for example, a SiN film or a SiCN film. Further, the liner film 106 has the effect of preventing oxidation of Cu.

As shown in FIGS. 11 and 12, the cap metal film 108 is formed over the Cu wire. In this configuration, the cap metal film 108 is formed to prevent Cu diffusion on the interface between the first Cu film 105 and the liner film 106.

In FIG. 12, reference numeral 109 denotes a second barrier metal film, reference numeral 110 denotes second Cu films, reference numeral 111 denotes holes, and reference numeral 112 denotes second Cu wires.

### DISCLOSURE OF THE INVENTION

### Problem to be Solved by the Invention

However, in the semiconductor device and the method for manufacturing the same according to the prior art (National Publication of International Patent Application No. 2003-505882), as shown in FIG. 10(e), the cap metal films 108 may be selectively formed in an imperfect manner by electroless plating and abnormally grown cap metal films 108′ and 108″ may be deposited on the first interlayer insulating film 101, so that particularly the cap metal film 108″ may cause a short circuit between the adjacent Cu wires.

The following will describe the causes of the deposition of the abnormally grown cap metal films 108′ and 108″ on the first interlayer insulating film 101.

The first cause is that when the displacement plating of Pd acting as catalysts is performed on the first Cu films 105, Pd is deposited also on the first interlayer insulating film 101 and the cap metal films 108′ and 108″ are formed also on the first interlayer insulating film 101 with Pd acting as nuclei on the first interlayer insulating film 101.

The second cause is (e.g., see Japanese Patent Laid-Open No. 2006-120664) the cap metal films abnormally grown from nuclei that are particles generated on the first interlayer insulating film 101 by metallic contamination or surface roughness on the first interlayer insulating film 101 or particles in an electroless plating solution.

Such abnormal cap metal films 108 on the first interlayer insulating film 101 have become apparent as semiconductor ICs have been reduced in size, thereby reducing the yields and reliability of semiconductor devices.

Thus in the formation of cap metal on wires, it is necessary to arrange cap metal films at certain intervals such that short circuits are prevented even when the metal is deposited on the interlayer insulating film between the wires. However, too large intervals may cause an EM failure.

According to another prior art example (e.g., see Japanese Patent Laid-Open No. 6-168942), regarding the resistance of Cu wires to EM, there is a critical length where the diffusion of atoms (or voids) by EM is balanced with diffusion performed in the reverse direction by a concentration gradient. EM failures do not occur at the critical length or lower.

In this case, the Cu wire has a critical length of 40 μm with a current density of 1×10⁷ A/cm² at 300° C. Thus the cap metal films 108, which are made of CoWP for suppressing the diffusion of atoms (or voids) on the surfaces of the Cu wires, are spaced at a distance of, e.g., 40 μm or less, thereby satisfying the need for sufficient resistance to EM.

The present invention has been devised to solve the problem of the prior art. An object of the present invention is to provide a semiconductor device and a method for manufacturing the same which can improve resistance to EM while reliably eliminating failures caused by short circuits between wires even when the semiconductor device is reduced in size.

### Means for Solving the Problem

In order to solve the problem, a semiconductor device of the present invention includes: a plurality of wires provided on an interlayer insulating film on a semiconductor substrate; and cap metal films formed on the top surfaces of the wires, wherein the cap metal film is partially formed on the top surface of the wire.

The semiconductor device according to the present invention, wherein the cap metal film is formed at a distance not larger than 40 μm from the cap metal film on the same wire.

The semiconductor device according to the present invention, wherein the cap metal films on the different wires are formed to be spaced at least 0.28 apart.

The semiconductor device according to the present invention, wherein the cap metal film is formed at a distance of at least 0.28 μl from a via for connecting the wire and the upper wiring of the wire.

The semiconductor device according to the present invention, wherein the cap metal film is made of a material selected from the group consisting of Co, a Co alloy, W, and a W alloy.

A method for manufacturing the semiconductor device of the present invention includes: (a) forming a plurality of wiring grooves on a first insulating film on a semiconductor substrate; (b) forming a plurality of wires by stacking conductive films in the plurality of wiring grooves after (a); (c) forming a second insulating film on the wires and the first insulating film after (b); (d) partially forming a plurality of openings on the wires so as to expose the surfaces of the wires on the second insulating film after (c); and (e) forming cap metal films on the wire surfaces exposed in the openings after (d).

The method for manufacturing the semiconductor device of the present invention, wherein (d) is a step of forming the openings with a resist mask, and (e) is a step of forming the cap metal films on the wire surfaces exposed in the openings, without removing the resist mask.

The method for manufacturing the semiconductor device of the present invention, wherein the method for manufacturing the semiconductor device according to the present invention further includes: (f) forming recessed portions on the exposed wire surfaces between (d) and (e).

The method for manufacturing the semiconductor device of the present invention, wherein the recessed portion is 10 nm to 30 nm in thickness.

The method for manufacturing the semiconductor device of the present invention, wherein the opening is formed at a distance not larger than 40 μm from the opening on the same wire in (d).

The method for manufacturing the semiconductor device of the present invention, wherein the openings on the different wires are spaced at least 0.28 μm apart in (d).

The method for manufacturing the semiconductor device of the present invention, wherein the opening is formed at a distance of at least 0.28 μm from a via for connecting the wire and the upper wiring of the wire in (d).

The method for manufacturing the semiconductor device of the present invention, wherein the cap metal film is formed by electroless plating.

The method for manufacturing the semiconductor device of the present invention, wherein the cap metal film is formed by chemical vapor deposition (CVD).

The method for manufacturing the semiconductor device of the present invention, wherein the cap metal film is made of a material selected from the group consisting of Co, a Co alloy, W, and a W alloy.

### ADVANTAGE OF THE INVENTION

As previously mentioned, according to the present invention, cap metal films formed on embedded wires can be sufficiently spaced.

Thus it is possible to improve resistance to EM while reliably eliminating failures caused by short circuits between the wires even when a semiconductor device is reduced in size.

### BRIEF DESCRIPTION OF THE DRAWINGS

FIG. 1 is a partial plan view showing the structure of a semiconductor device according to a first embodiment of the present invention;

FIG. 2 is a sectional view showing the semiconductor device taken along line A-A′ of FIG. 1 according to the first embodiment;

FIG. 3 is a sectional view showing the semiconductor device taken along line B-B′ of FIG. 1 according to the first embodiment;

FIG. 4 is a sectional view showing a first modification of the semiconductor device according to the first embodiment;

FIG. 5 is a sectional view showing a second modification of the semiconductor device according to the first embodiment;

FIG. 6 is a sectional view showing the steps of a method for manufacturing the semiconductor device according to the first embodiment;

FIG. 7 is a sectional view showing the steps of a method for manufacturing a semiconductor device according to a second embodiment of the present invention;

FIG. 8 is a sectional view showing the steps of a method for manufacturing a semiconductor device according to a third embodiment of the present invention;

FIG. 9 is a sectional view showing the steps of the method for manufacturing the semiconductor device in the event of lithography misalignment in the formation of openings according to the third embodiment;

FIG. 10 is a sectional view showing the steps of a method for manufacturing a semiconductor device according to the prior art;

FIG. 11 is a partial plan view showing the structure of the semiconductor device according to the prior art;

FIG. 12 is a sectional view showing the semiconductor device taken along line A-A′ of FIG. 11 according to the prior art; and

FIG. 13 is an explanatory drawing showing the relationship between a leakage current between wires and a distance between the wires, in the case where a cap metal film made of CoWP is formed on the Cu wire and in the case where the cap metal film is not formed on the Cu wire.

### BEST MODE FOR CARRYING OUT THE INVENTION

A semiconductor device and a method for manufacturing the same according to embodiments of the present invention will be specifically described below with reference to the accompanying drawings.

### First Embodiment

The following will discuss a semiconductor device and a method for manufacturing the same according to a first embodiment of the present invention.

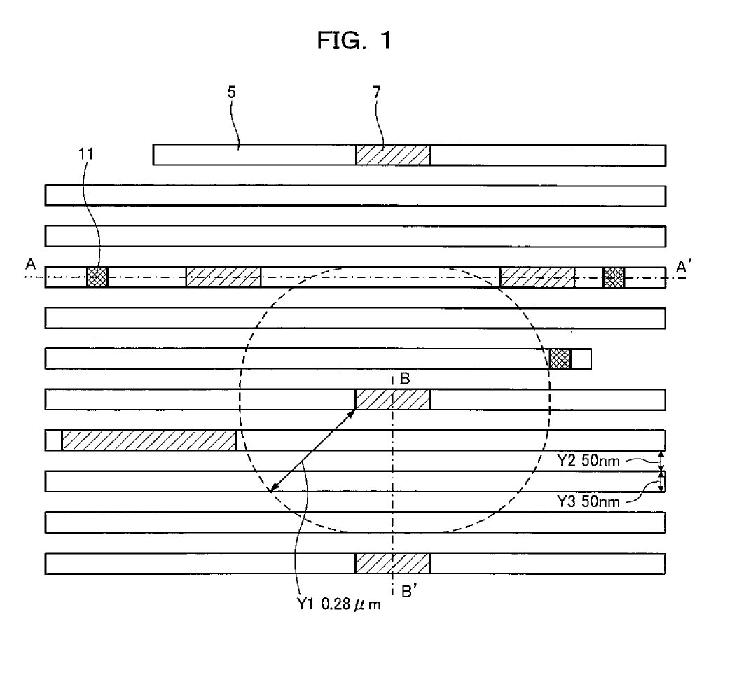

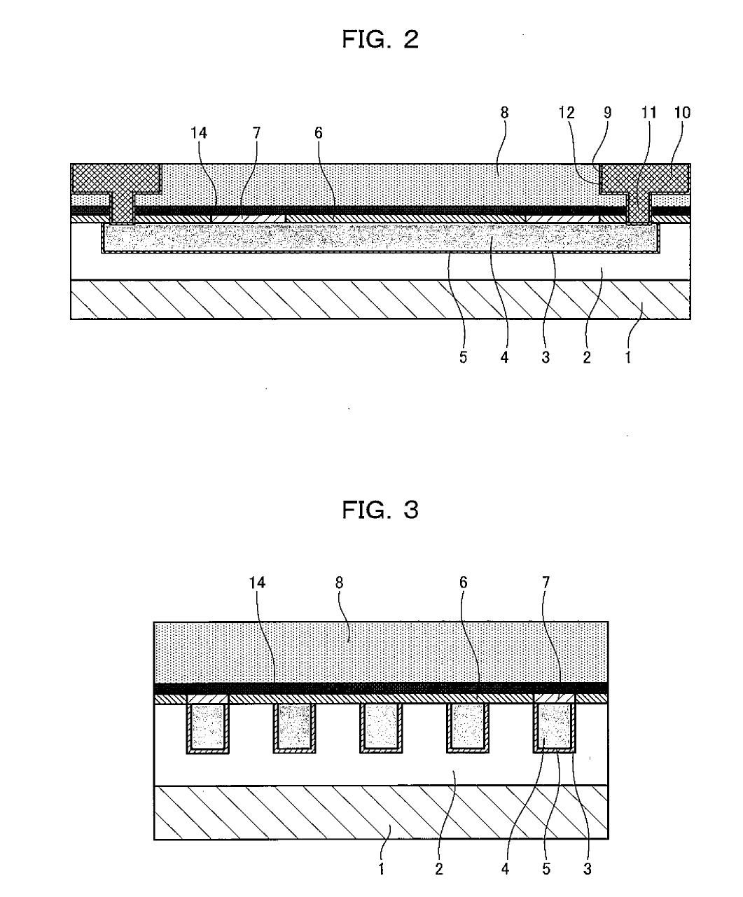

FIG. 1 shows a part of a plan view illustrating the structure of the semiconductor device according to the first embodiment. FIG. 2 is a sectional view showing the semiconductor device taken along line A-A′ of FIG. 1 according to the first embodiment. FIG. 3 is a sectional view showing the semiconductor device taken along line B-B′ of FIG. 1 according to the first embodiment.

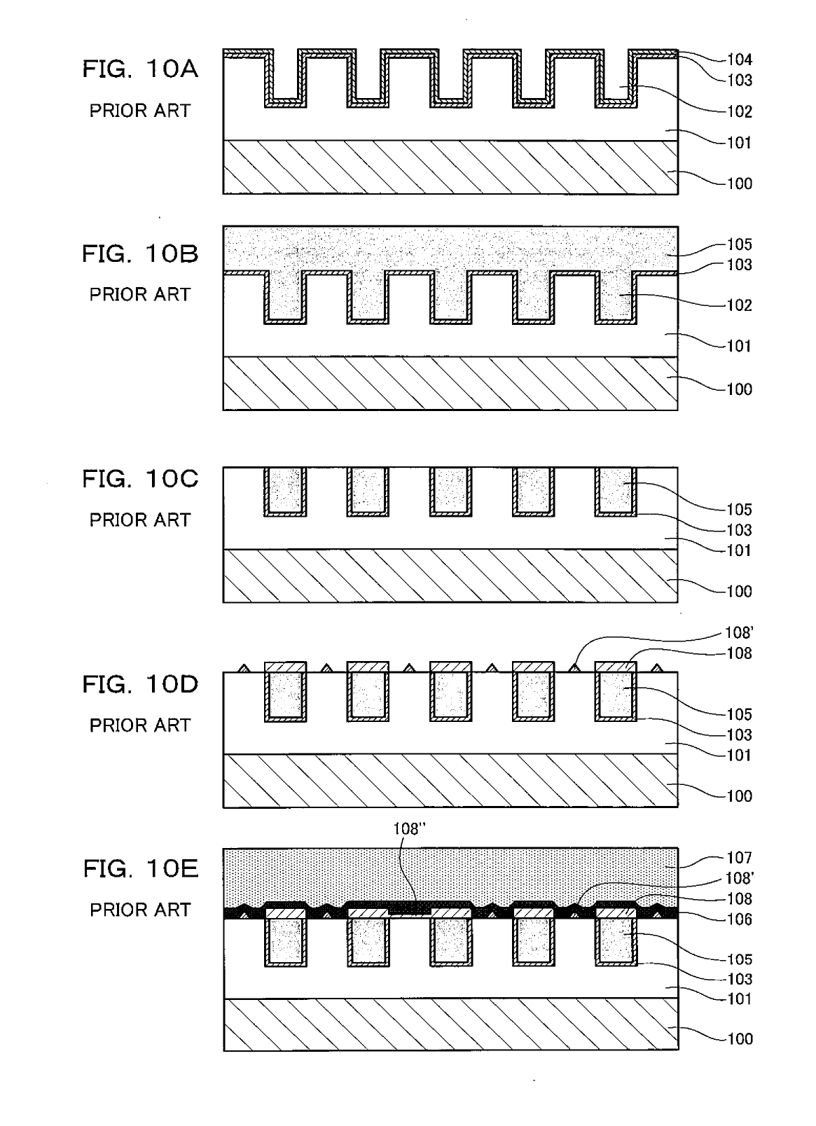

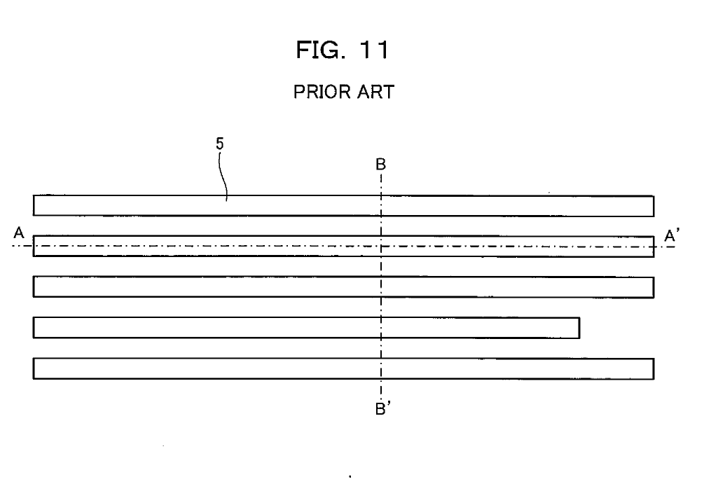

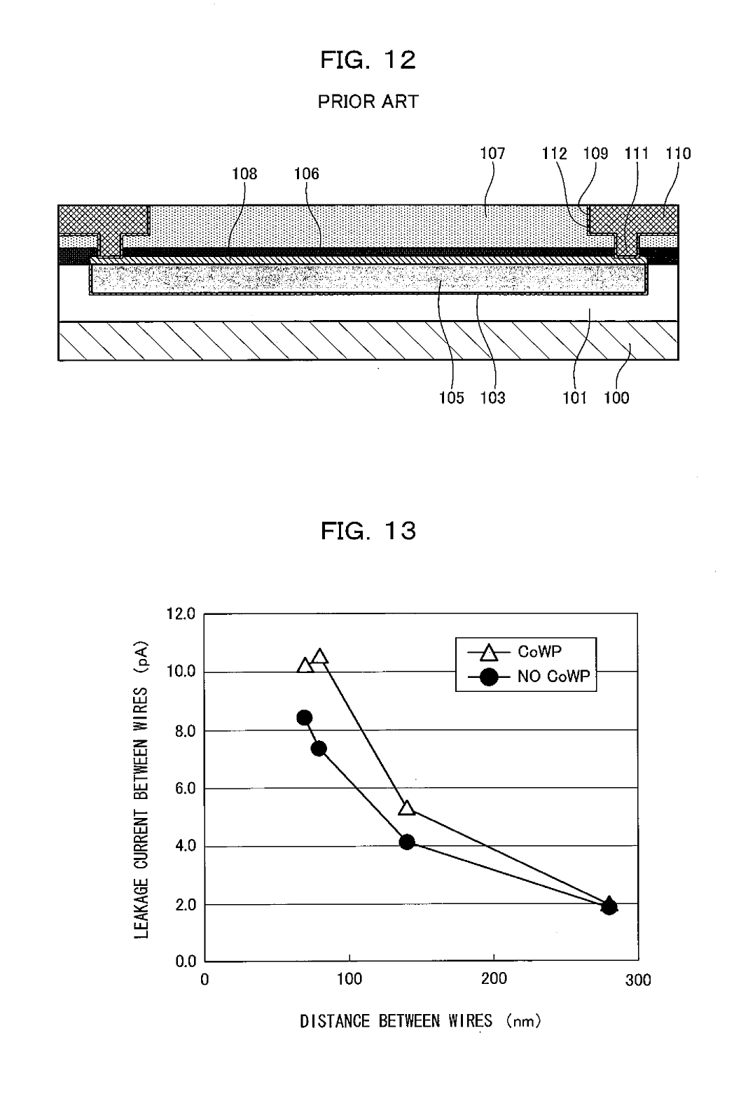

As is understood from comparisons between FIGS. 1 and 11, FIGS. 2 and 12, and FIGS. 3 and 10(e), a cap metal film 7 partially covers a first Cu wire 5 in the semiconductor device of the first embodiment.

In FIG. 1, the first Cu wires 5 are formed on a first interlayer insulating film 2. In this configuration, the first Cu wire 5 is formed of a first Cu film 4 and a first barrier metal film 3 covering the sides and bottom of the first Cu film 4.

In FIG. 2, second Cu wires 12 formed on a second interlayer insulating film 8 are each formed of a second Cu film 10 and a second barrier metal film 9. The second Cu wires 12 are electrically connected to the first Cu wires 5 via holes 11.

As shown in FIG. 3, a first liner film 6 is formed on the first Cu wires 5 and the first interlayer insulating film 2. For example, the first liner film 6 is a film such as a SiN film and a SiCN film. Further, on the first Cu wire 5, the cap metal film 7 made up of a CoWP film is partially formed. The length of the cap metal film 7 in the longitudinal direction of the Cu wire is not particularly limited but may be longer than or equal to, for example, a minimum line width. Further, the length of the cap metal film 7 may vary with the maximum current density of the Cu wire.

A feature of the semiconductor device of the first embodiment is that the cap metal film 7 is partially formed on the Cu wire at least at a desired distance from the cap metal film 7 not formed on the same Cu wire. Consequently, even when the cap metal film 7 selectively grown on the first Cu wire 5 is formed on the first interlayer insulating film 2, it is possible to prevent short circuits between the Cu wires. In this case, the desired distance is at least 0.28 μm as indicated by an arrow Y1.

The cap metal films 7 formed on the same Cu wire are desirably spaced at a distance of 40 μm or less. Thus without forming the cap metal film 7 over the Cu wire, it is possible to sufficiently suppress copper diffusion and improve resistance to EM. Moreover, the cap metal films 7 formed on the same Cu wire can be spaced at any distance of 40 μm or less, so that a distance between the cap metal films 7 formed on the different Cu wires can be set at a desired value and it is possible to considerably reduce short circuits between the Cu wires.

For the same reason, a distance between the cap metal film 7 formed on the first Cu wire 5 and the hole 11 not formed on the same Cu wire is at least 0.28 μm as indicated by the arrow Y1, thereby preventing a short circuit between the Cu wire and the hole 11.

The following will describe the reason why the cap metal films 7 formed on the different Cu wires are desirably separated from each other at a distance of at least 0.28 μm as indicated by the arrow Y1.

The present inventor examined the relationship between an amount of leakage current between the Cu wires and a distance between the Cu wires, in the case where the cap metal film 7 made up of a CoWP film is formed on the Cu wire and in the case where the cap metal film 7 is not formed on the Cu wire. The result is shown in FIG. 13.

In FIG. 13, the horizontal axis represents a distance between the wires (unit: nm) and the vertical axis represents an amount of leakage current (unit: pA) between the wires. Triangles represent the relationship between a distance between the wires and an amount of leakage current between the wires when the cap metal film 7 is formed on the first Cu wire 5. Circles represent the relationship between a distance between the wires and an amount of leakage current between the wires when the cap metal film 7 is not formed on the first Cu wire 5.

As shown in FIG. 13, a distance of 0.14 μm or less between the wires increases a leakage current value when the cap metal film 7 is formed on the first Cu wire 5, whereas a distance not smaller than 0.28 μm between the wires hardly causes leakage current between the wires regardless of the presence or absence of the cap metal film 7.

Thus the problem of leakage current between the wires can be solved by setting a distance of at least 0.28 μm between the cap metal films 7 selectively grown on the different wires.

Further, regarding the resistance of the Cu wires to EM, there is a critical length where the diffusion of atoms (or voids) by EM is balanced with diffusion performed in the reverse direction by a concentration gradient. EM failures do not occur at the critical length or lower. In this case, the Cu wire has a critical length of 40 μm with a current density of 1×10⁷ A/cm² at 300° C.

Thus the cap metal films 7, each of which includes a CoWP film for suppressing the diffusion of atoms (or voids) on the surfaces of the Cu wires, are spaced at a distance of, e.g., 40 μm or less, thereby improving the resistance to EM.

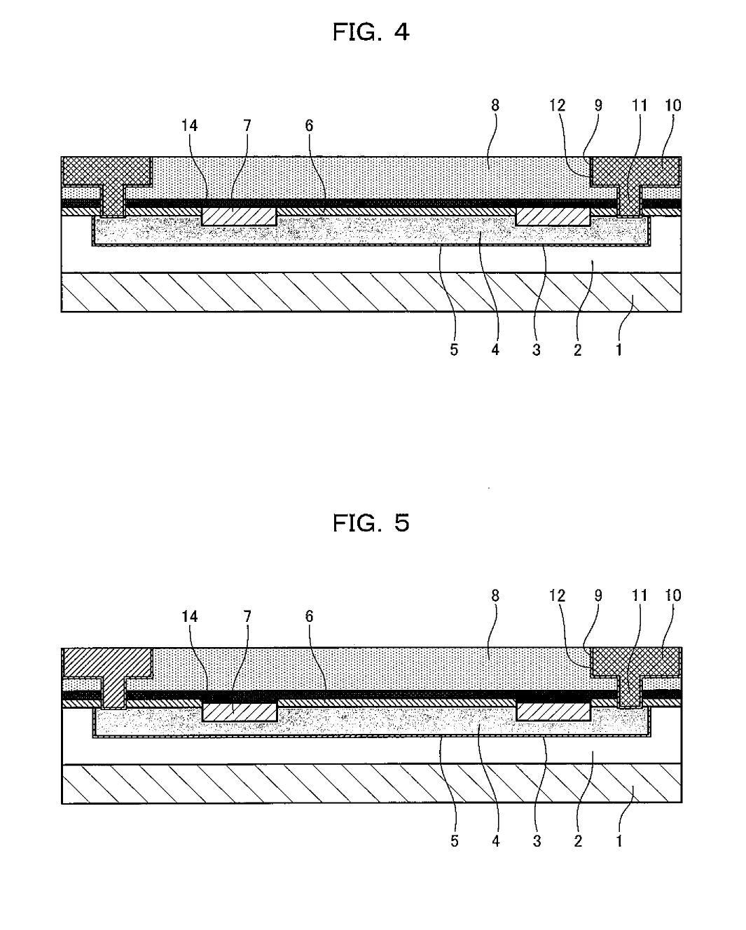

As shown in FIG. 1, the cap metal films 7 are formed on the surfaces of the Cu wires in the first embodiment. As shown in FIG. 4, the cap metal films 7 may be formed in recessed portions formed on the first Cu wire 5.

As shown in FIG. 5, the surface of the first liner film 6 and the surface of the cap metal film 7 may not be flush with each other.

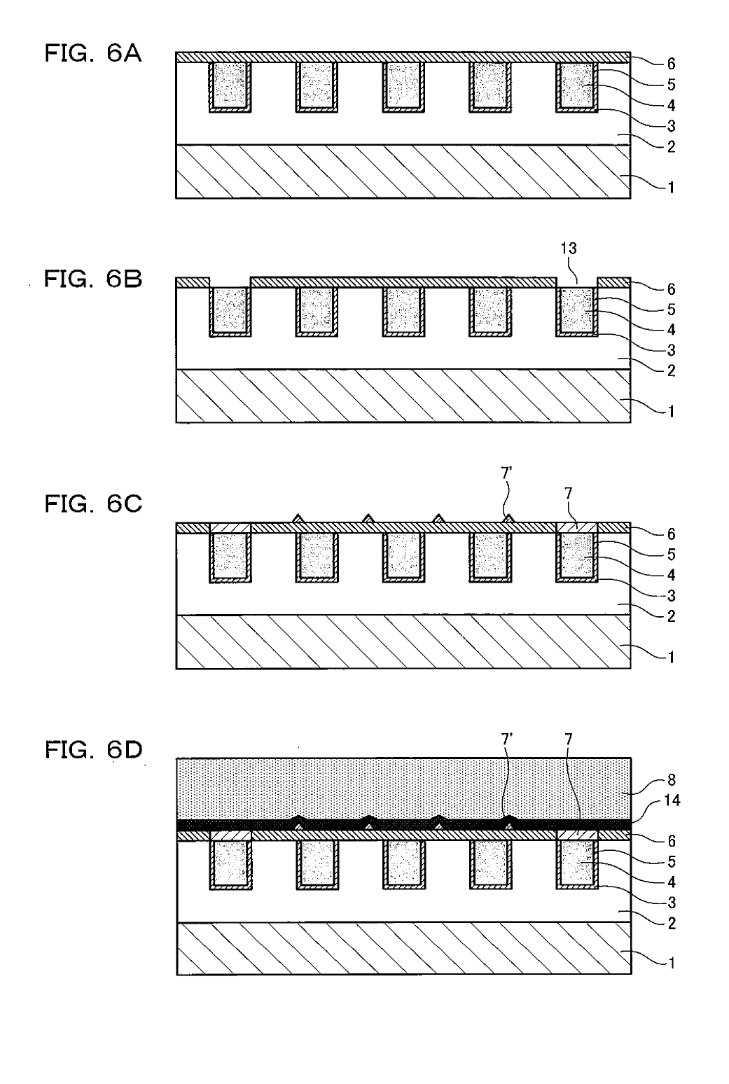

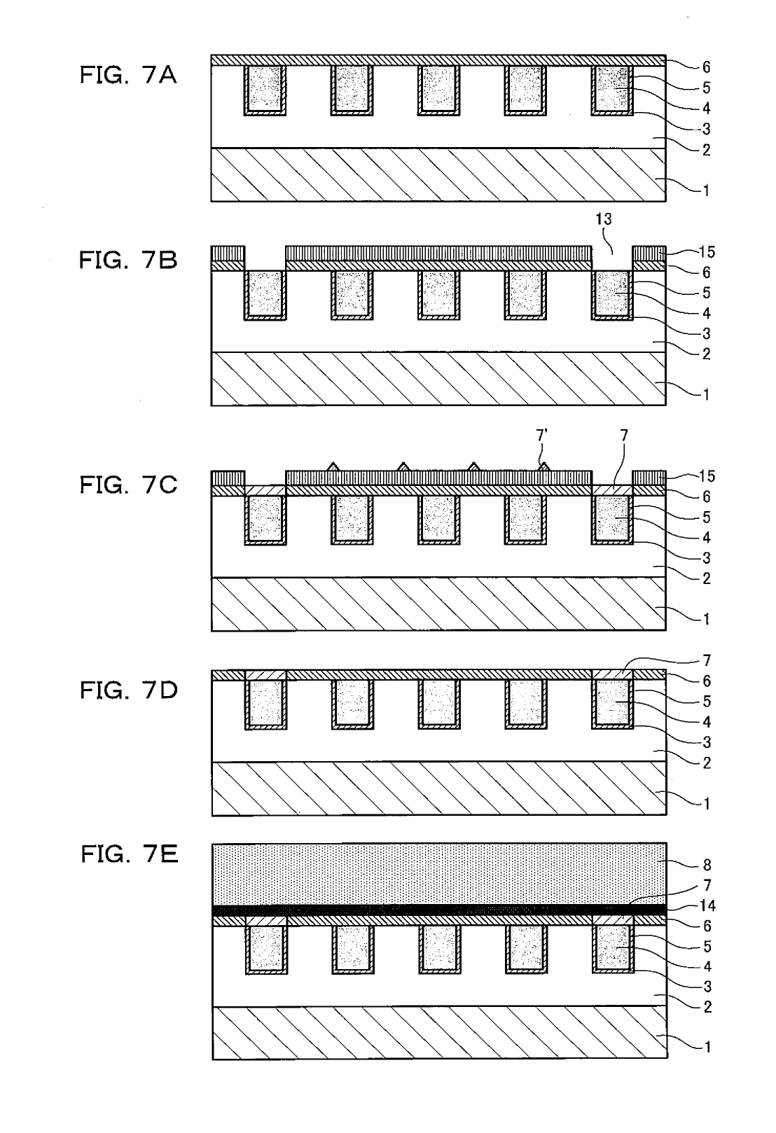

Referring to FIGS. 6(a) to 6(d), the following will describe a method for manufacturing the semiconductor device of the first embodiment.

First, as shown in FIG. 6(a), the first interlayer insulating film 2 is formed on the semiconductor substrate 1. After that, wiring grooves are formed on the first interlayer insulating film 2, and then the first barrier metal films 3 and the first Cu films 4 are stacked in the wiring grooves to form the first Cu wires 5. The first liner film 6 is then formed on the first Cu wires 5 and the first interlayer insulating film 2. The first liner film 6 may be an insulating film not oxidizing the first Cu wires 5 during the film formation. For example, the first liner film 6 may be a film such as a silicon nitride film (SiN) and a SiCN film.

Next, as shown in FIG. 6(b), openings 13 are formed on the first liner film 6 by using lithography and dry etching, so that the Cu surfaces of the first Cu wires 5 are partially exposed. In the case of lithography, a used resist material is removed after that. In this configuration, the openings 13 formed on the different Cu wires are spaced at a distance of at least 0.28 μm. Further, the openings 13 formed on the same Cu wire are spaced at a distance of 40 μm or less. When vias (not shown) are formed for connection with upper wiring from the first Cu wire 5, the vias are formed such that the Cu wire having the vias is formed at a distance of at least 0.28 μm from the opening not formed on the same Cu wire. Thus like between the wires, it is possible to prevent leakage current between the vias and the wire on which cap metal has grown, the leakage current being caused by degradation of selectivity when the cap metal is stacked.

Next, as shown in FIG. 6(c), the cap metal films 7 including CoWP films are selectively grown by electroless plating on the Cu surfaces exposed in the openings 13. A method for forming the cap metal film 7 will be described below. First, Pd is deposited on the Cu surface with a Pd ion serving as a catalyst. After that, the cap metal film 7 is formed on the Cu surface with Pd serving as a nucleus, by using H₂PO₂ as a reducing agent and using a solution containing Co ions and W ions as an electroless plating solution.

Next, as shown in FIG. 6(d), a second liner film 14 is stacked on the cap metal films 7 and the first liner film 6 to prevent the oxidation of the cap metal films 7. For example, the second liner film 14 may be a film such as a silicon nitride film (SiN) and a SiCN film. After that, the second interlayer insulating film 8 is stacked on the second liner film 14.

Upon stacking of the second interlayer insulating film 8, in the case where the cap metal film made of a material such as CoWP is not oxidized or the degree of oxidation is negligible, the step of forming the second liner film 14 may be omitted.

A feature of the method for manufacturing the semiconductor device of the first embodiment is that the cap metal film 7 is partially formed at a desired distance or a larger distance from the cap metal film 7 not formed on the same Cu wire. Consequently, even when the cap metal film selectively grown on the Cu wire is formed on the first interlayer insulating film 2, it is possible to prevent short circuits between the wires. In this case, the desired distance is at least 0.28 μm. The cap metal films 7 formed on the same Cu wire are desirably spaced at a distance of 40 μm or less.

Thus without forming the cap metal film over the Cu wire, it is possible to sufficiently suppress copper diffusion and improve resistance to EM. Moreover, the cap metal films formed on the same Cu wire can be spaced at any distance of 40 μm or less.

Therefore, a distance between the cap metal films formed on the different wires can be set at a desired value and it is possible to suppress short circuits between the wires.

In the first embodiment, the cap metal films 7 are formed on the surfaces of the Cu wires. Recessed portions may be formed on the Cu wires and the cap metal films may be formed in the recessed portions. Moreover, the cap metal film 7 may be formed such that the surface of the first liner film 6 and the surface of the cap metal film 7 are not flush with each other.

### Second Embodiment

The following will describe a semiconductor device and a method for manufacturing the same according to a second embodiment of the present invention.

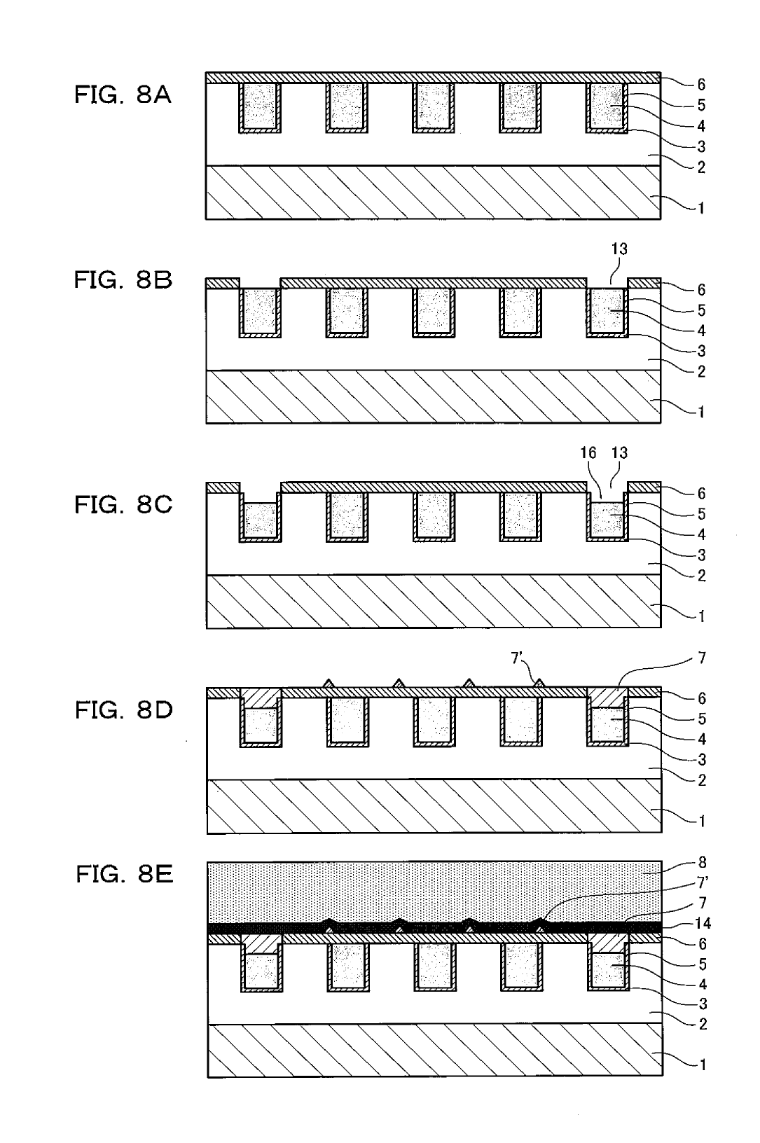

FIG. 7 is a sectional view showing the steps of the manufacturing method of the semiconductor device according to the second embodiment.

First, the step of forming the sectional view of FIG. 7(a) is the same as the step of forming the sectional view of FIG. 6(a) and thus the explanation thereof is omitted.

Next, as shown in FIG. 7(b), a resist film 15 is formed and openings 13 are formed on a first liner film 6 by using lithography and dry etching, so that the Cu surfaces of first Cu wires 5 are partially exposed. The resist film used at this point is not removed but is left at least on a part other than the openings 13. The openings 13 are formed at the same positions as in the sectional view of FIG. 6(b) and thus the explanation of the positions is omitted.

After that, as shown in FIG. 7(c), cap metal films 7 each of which is made up of a CoWP film are selectively grown by electroless plating on the Cu surfaces exposed in the openings 13. A specific method is the same as in the sectional view of FIG. 6(c) and thus the explanation thereof is omitted. At this point, the resist film 15 is hydrophobic and thus hardly leaks to an electroless plating solution. Thus the cap metal films 7 are hardly deposited on the resist film 15.

Next, as shown in FIG. 7(d), the resist film 15 is removed by a typical ashing technique and cleaning technique. The resist film 15 is hydrophobic and thus the cap metal films 7 are hardly deposited on the resist film 15. Even if a cap metal film 7′ is deposited on the resist film 15, the cap metal film 7′ is lifted off and removed at the removal of the resist film 15. Thus leakage does not occur between the wires.

The step of forming the sectional view of FIG. 7(e) is the same as the step of forming the sectional view of FIG. 6(d) and thus the explanation thereof is omitted.

As compared with the first embodiment, in the method for manufacturing the semiconductor device of the second embodiment, the cap metal films 7 are stacked in the openings 13 in a state in which the resist film 15 is left on a part other than the openings 13, and then the cap metal film 7′ deposited on the resist film 15 is removed. Thus it is possible to achieve the effect of removing the cap metal film 7′ with higher reliability.

### Third Embodiment

The following will describe a semiconductor device and a method for manufacturing the same according to a third embodiment of the present invention.

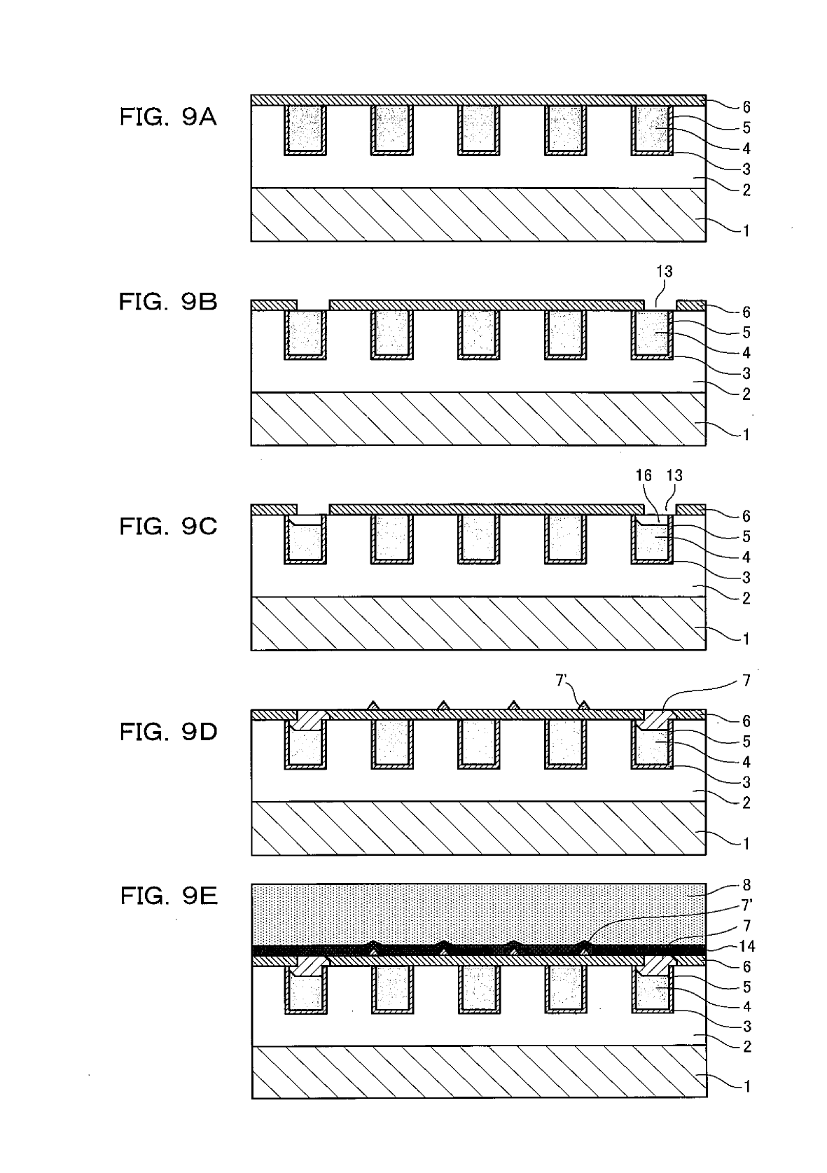

FIG. 8 is a sectional view showing the steps of the manufacturing method of the semiconductor device according to the third embodiment.

First, the steps of forming the sectional views of FIGS. 8(a), 8(b), 8(d), and 8(e) are the same as the steps of forming the sectional views of FIGS. 6(a), 6(b), 6(c), and 6(d) and thus the explanation thereof is omitted. Only the step of forming the sectional view of FIG. 8(c) will be described below.

Next, as shown in FIG. 8(c), the surfaces of first Cu films 4 are removed by about 10 nm to 30 nm by wet etching or isotropic dry etching. In this case, etching may involve ashing (plasma treatment containing oxygen) for removing a resist film and involve cleaning using a polymer cleaning solution and so on.

In the method for manufacturing the semiconductor device of the third embodiment, recessed portions 16 are formed on the Cu films of openings 13 by isotropic etching, and then cap metal films 7 are formed by electroless plating.

Thus even when lithography misalignment occurs in the formation of the openings 13, the top surfaces of Cu wires can be always covered with CoWP films. Generally, a maximum lithography misalignment is about 10 nm to 30 nm and thus a recess amount may be determined according to the maximum misalignment. Thus it is possible to prevent reliability from decreasing in the event of misalignment.

FIGS. 9(a) to 9(e) are sectional views showing the steps of forming the semiconductor device according to the manufacturing method of the third embodiment when lithography misalignment occurs during the formation of the openings 13. As shown in FIG. 9(e), the recessed portions 16 are formed on the Cu film surfaces of the openings 13, so that the top surfaces of the Cu wires can be reliably covered with the cap metal films 7.

In the second embodiment, the same effect can be obtained by forming recessed portions on the Cu films of the openings 13 by isotropic etching and then forming the cap metal films 7 by electroless plating.

In the first to third embodiments, pure Cu is used for the first Cu film 4 and the second Cu film 10 but a Cu alloy film may be used instead. For example, the first barrier metal film 3 and the second barrier metal film 9 each have a TaN/Ta laminated structure (unless otherwise specified, a laminated film is represented in the order of film formation and thus TaN/Ta indicates that TaN is stacked and then a Ta film is stacked thereon) but may be made of other materials as long as the barrier metal film has adhesion with Cu and a Cu barrier property.

The conductive cap metal film 7 partially formed on the first Cu wire 5 is a CoWP film. The cap metal film 7 may be a conductive film that is made of a material such as CoSnP, CoP, Pd, In, W, COB, CoSnB, CoWB, and NIB and can be formed by electroless plating and a conductive film that is made of a material such as Pd, In, W, and Co and can be stacked by selective chemical vapor deposition (CVD).

The first to third embodiments described the methods for eliminating leakage current between the cap metal films 7 formed on the first Cu wires 5. For the same reason, the cap metal film 7 on the first Cu wire 5 and the hole connected to upper wiring are spaced at least 0.28 μm apart, so that leakage can be prevented also between the cap metal film 7 and the hole 11.

### INDUSTRIAL APPLICABILITY

A semiconductor device and a method for manufacturing the same according to the present invention can improve resistance to EM while reliably eliminating failures caused by short circuits between wires even when the semiconductor device is reduced in size. Thus the present invention is useful for forming micro wiring and the like with high yields and high reliability.

1. A semiconductor device comprising:
a plurality of wires provided on an interlayer insulating film on a semiconductor substrate; and
cap metal films formed on top surfaces of the wires,
wherein the cap metal film is partially formed on the top surface of the wire.

2. The semiconductor device according to claim 1, wherein the cap metal film is formed at a distance not larger than 40 μm from the cap metal film on the same wire.

3. The semiconductor device according to claim 2, wherein the cap metal films on the different wires are formed to be spaced at least 0.28 μm apart.

4. The semiconductor device according to claim 2, wherein the cap metal film is formed at a distance of at least 0.28 μm from a via for connecting the wire and upper wiring of the wire.

5. The semiconductor device according to claim 1, wherein the cap metal film is made of a material selected from the group consisting of Co, a Co alloy, W, and a W alloy.

6. A method for manufacturing a semiconductor device, comprising:
(a) forming a plurality of wiring grooves on a first insulating film on a semiconductor substrate;
(b) forming a plurality of wires by stacking conductive films in the plurality of wiring grooves after (a);
(c) forming a second insulating film on the wires and the first insulating film after (b);
(d) partially forming a plurality of openings on the wires so as to expose surfaces of the wires on the second insulating film after (c); and
(e) forming cap metal films on the wire surfaces exposed in the openings after (d).

7. The method for manufacturing a semiconductor device according to claim 6, wherein (d) is a step of forming the openings with a resist mask, and
(e) is a step of forming the cap metal films on the wire surfaces exposed in the openings, without removing the resist mask.

8. The method for manufacturing a semiconductor device according to claim 6, further comprising (f) forming recessed portions on the exposed wire surfaces between (d) and (e).

9. The method for manufacturing a semiconductor device according to claim 8, wherein the recessed portion is 10 nm to 30 nm in thickness.

10. The method for manufacturing a semiconductor device according to claim 6, wherein the opening is formed at a distance not larger than 40 μm from the opening on the same wire in (d).

11. The method for manufacturing a semiconductor device according to claim 10, wherein the openings on the different wires are spaced at least 0.28 μm apart in (d).

12. The method for manufacturing a semiconductor device according to claim 10, wherein the opening is formed at a distance of at least 0.28 μm from a via for connecting the wire and upper wiring of the wire in (d).

13. The method for manufacturing a semiconductor device according to claim 6, wherein the cap metal film is formed by electroless plating.

14. The method for manufacturing a semiconductor device according to claim 6, wherein the cap metal film is formed by chemical vapor deposition (CVD).

15. The method for manufacturing a semiconductor device according to claim 6, wherein the cap metal film is made of a material selected from the group consisting of Co, a Co alloy, W, and a W alloy.
